(19) United States
(12) Patent Application Publication
(10) Pub. No.: US 2014/0145315 A1
(43) Pub. Date: May 29, 2014

(54) SEMICONDUCTOR DEVICE AND METHOD OF FABRICATING THE SAME

(71) Applicant: Samsung Electronics Co., Ltd., Suwon-si (KR)

(72) Inventor: Gwang-Man LIM, Seoul (KR)

(73) Assignee: Samsung Electronics Co., Ltd., Suwon-si (KR)

(21) Appl. No.: 14/071,877

(22) Filed: Nov. 5, 2013

(30) Foreign Application Priority Data
Nov. 23, 2012 (KR) 10-2012-0133853

(51) Int. Cl. H01L 23/552; H01L 21/56

(52) U.S. Cl. CPC H01L 23/552; H01L 21/56
USPC 257/659; 438/126

(57) ABSTRACT

Provided are a semiconductor device and a method of fabricating the same. The semiconductor device includes a substrate, a connection member formed on a top surface of the substrate, a semiconductor package mounted on the connection member, an encapsulation member formed to fill a space between a top portion of the substrate and a bottom portion of the semiconductor package, and a shielding material formed to cover the semiconductor package and the encapsulation member.

### CROSS-REFERENCE TO RELATED APPLICATIONS

This application claims priority under 35 U.S.C. §119(a) from Korean Patent Application No. 10-2012-0133853 filed on Nov. 23, 2012 in the Korean Intellectual Property Office, the contents of which in its entirety are herein incorporated by reference.

### BACKGROUND

1. Field of the Invention

The present general inventive concept relates to a semiconductor device and a method of fabricating the same.

2. Description of the Related Art

Recently, the demand for compact, light-weight electronic products has continuously been increasing. In order to manufacture compact, light-weight electronic products, a technology to reduce the individual sizes of mounting components have been required. In addition, a system on chip (SOC) technology integrating a plurality of individual elements in a single chip, a system in package (SIP) technology integrating a plurality of individual elements in a single package, or the like.

In particular, it has been demanded that a high frequency semiconductor package handling a high frequency signal includes various electromagnetic shielding structures in order to implement excellent electromagnetic interference (EMI) and electromagnetic susceptibility (EMS) characteristics as well as a compact size. To this end, research into various structures capable of shielding electromagnetic waves is under way.

### SUMMARY

Exemplary embodiments of the present general inventive concept provide a semiconductor device having an EMI shielding structure, which reduces a mounting space of the semiconductor device.

The present general inventive concept also provides a method of fabricating a semiconductor device having an EMI shielding structure, which reduces a mounting space of the semiconductor device.

Additional features and utilities of the present general inventive concept will be set forth in part in the description which follows and, in part, will be obvious from the description, or may be learned by practice of the general inventive concept.

These and other objects of the present inventive concept will be described in or be apparent from the following description of the preferred exemplary embodiments of the present general inventive concept.

Exemplary embodiments of the present general inventive concept provide a semiconductor device including a substrate, a connection member formed on a top surface of the substrate, a semiconductor package mounted on the connection member, an encapsulation member formed to fill a space between a top portion of the substrate and a bottom portion of the semiconductor package, and a shielding material formed to cover the semiconductor package and the encapsulation member.

The semiconductor package may be coated with a metallic material.

The substrate may include at least one metal pad. The metal pad may be electrically connected to a ground and the shielding material.

The semiconductor package may include at least one metal pad. The metal pad may be electrically connected to a ground and the shielding material.

Exemplary embodiments of the present general inventive concept also provide a semiconductor device including a substrate, a connection member formed on a top surface of the substrate, a semiconductor package mounted on the connection member and coated with a metallic material, an encapsulation member formed to fill a space between a top portion of the substrate and a bottom portion of the semiconductor package, and an epoxy material covering the encapsulation member and formed in contact with the metallic material.

The semiconductor device may further include a shielding material formed to cover the semiconductor package and the epoxy material.

The substrate may include at least one metal pad. The metal pad may be electrically connected to a ground and be formed in contact with the epoxy material.

The semiconductor package may include at least on metal pad. The metal pad may be electrically connected to a ground and the metallic material.

Exemplary embodiments of the present general inventive concept also provide a method of fabricating a semiconductor device, the method including forming a connection member on a top surface of a substrate, mounting a semiconductor package on the connection member, injecting an encapsulation member to fill a space between a top portion of the substrate and a bottom portion of the semiconductor package, and forming a shielding material to cover the semiconductor package and the encapsulation member.

The method may further include forming at least one metal pad on the substrate. The metal pad may be electrically connected to a ground and the shielding material.

The method may further include forming a dam on the top surface of the substrate to prevent the encapsulation member from covering the metal pad between the mounting of the semiconductor package and the injecting of the encapsulation member.

The method may further include forming at least one metal pad on the semiconductor package. The metal pad may be electrically connected to a ground and the shielding material.

The method may further include forming at least on first metal pad on the substrate, the at least one first metal pad being electrically connected to a ground and the shielding material, and forming at least one second metal pad on the semiconductor package, the at least one second metal pad being electrically connected to the ground and the shielding material.

Exemplary embodiments of the present general inventive concept also provide a method of fabricating a semiconductor device, the method including forming a connection member on a top surface of the substrate, mounting a semiconductor package coated with a metallic material on the connection member, injecting an encapsulation member to fill a space between a top portion of the substrate and a bottom portion of the semiconductor package, and forming an epoxy material to cover the encapsulation member, the epoxy material being formed in contact with the metallic material.

The method may further include forming a shielding material covering the semiconductor package and the epoxy material.

Exemplary embodiments of the present general inventive concept also provide a semiconductor device including a first substrate, a connection member formed on a top surface of the first substrate, a semiconductor package mounted on the connection member, an encapsulation member formed to fill a space between a top portion of the first substrate and a bottom portion of the semiconductor package, and a covering material formed to cover the encapsulation member and at least a portion of the semiconductor package.

The covering material may be a shielding material to shield against electromagnetic waves.

The semiconductor device may further include a metal pad formed on the first substrate, the metal pad being electrically connected to a ground and the shielding material, and a dam formed on the top surface of the first substrate between the encapsulation member and the metal pad.

The semiconductor package may include a second substrate, and at least one metal pad formed on the second substrate, the metal pad being electrically connected to a ground and to the shielding material.

The semiconductor package may include a second substrate, and at least one metal pad formed on a portion of the semiconductor package other than the second substrate, the metal pad being electrically connected to a ground and to the shielding material.

The portion of the semiconductor package covered by the covering material may be coated with a metallic material.

The covering material may contact the metallic material.

The covering material may be a shielding material to shield against electromagnetic waves.

The covering material may be an epoxy.

The covering material may be disposed to cover the semiconductor package.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view showing a semiconductor device according to an exemplary embodiment of the present inventive concept;

FIG. 2 is a cross-sectional view showing a semiconductor device according to another exemplary embodiment of the present inventive concept;

FIGS. 3 and 4 are cross-sectional views showing a semiconductor device according to still another exemplary embodiment of the present inventive concept;

FIG. 5 is a cross-sectional view showing a semiconductor device according to still another exemplary embodiment of the present inventive concept;

FIGS. 6 and 7 are cross-sectional views showing a semiconductor device according to still another exemplary embodiment of the present inventive concept;

FIGS. 8 to 10 are cross-sectional views showing a semiconductor device according to still another exemplary embodiment of the present inventive concept;

FIG. 11 is a cross-sectional view showing a semiconductor device according to still another exemplary embodiment of the present inventive concept;

FIGS. 12 and 13 illustrate a method for fabricating a semiconductor device according to an exemplary embodiment of the present inventive concept;

FIGS. 14 and 15 illustrate a method for fabricating a semiconductor device according to another exemplary embodiment of the present inventive concept;

FIGS. 16 and 17 illustrate a method for fabricating a semiconductor device according to still another exemplary embodiment of the present inventive concept;

FIG. 18 is a block diagram of an electronic system incorporating a semiconductor device according to some exemplary embodiments of the present general inventive concept; and

FIGS. 19 and 20 illustrate exemplary semiconductor systems to which a semiconductor device according to some exemplary embodiments of the present inventive concept can be applied.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. These exemplary embodiments are provided so that this disclosure will be thorough and complete, and will fully convey the scope of the present general inventive concept to those skilled in the art. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a,” “an” and “the” and similar referents in the context of describing the present general inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which the present general inventive concept belongs. It is noted that the use of any and all examples, or exemplary terms provided herein is intended merely to better illuminate the present general inventive concept and is not a limitation on the scope of the present general inventive concept unless otherwise specified. Further, unless defined otherwise, all terms defined in generally used dictionaries may not be overly interpreted.

The present general inventive concept will be described with reference to perspective views, cross-sectional views, and/or plan views, in which exemplary embodiments of the present general inventive concept are illustrated. Thus, the profile of an exemplary view may be modified according to manufacturing techniques and/or allowances. That is, the exemplary embodiments of the present general inventive concept are not intended to limit the scope of the present general inventive concept but cover all changes and modifications that can be caused due to a change in manufacturing process. Thus, regions illustrated in the drawings are illustrated in schematic form and the shapes of the regions are presented simply by way of illustration and not as a limitation.

In the following semiconductor device and the method of fabricating the same according to the present general inventive concept, the semiconductor device has an EMI shielding structure, which reduces a mounting space of the semiconductor device. Conventionally, a structure capable of shielding electromagnetic waves using a shielding can or a shielding sheet has been proposed. However, the proposed structure may increase a mounting space of the semiconductor device.

In a case where a metal is coated on only the semiconductor package, the mounting space of the semiconductor device can be reduced, but it is still necessary to increase the EMI shielding effect. In the present general inventive concept, an EMI shielding structure is formed not only on semiconductor package but also on a lower region thereof the semiconductor package.

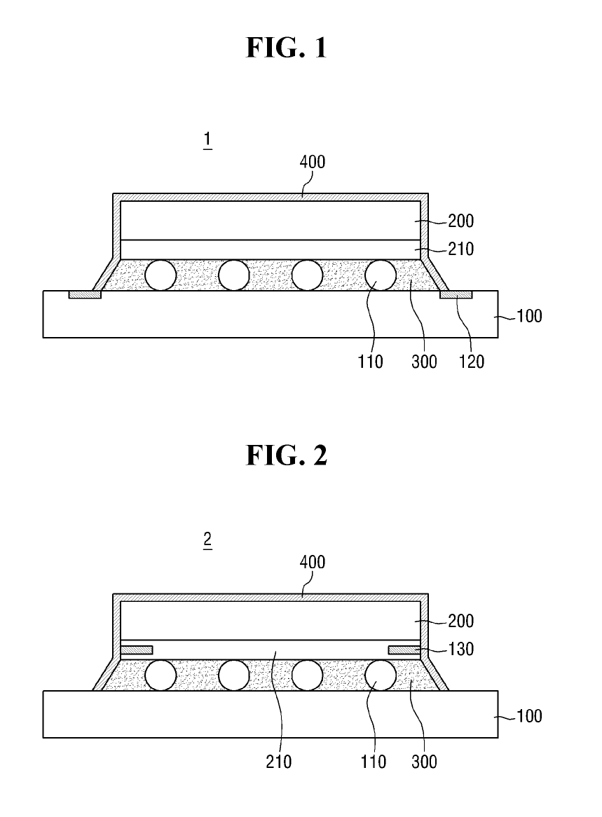

FIG. 1 is a cross-sectional view illustrating a semiconductor device 1 according to an exemplary embodiment of the present general inventive concept.

Referring to FIG. 1, the semiconductor device 1 may include a substrate 100, a connection member 110, a first metal pad 120, a semiconductor package 200, an encapsulation member 300, and a shielding material 400.

The substrate 100 may be a packaging substrate or a main substrate. The substrate 100 may be, for example, a printed circuit board, or a ceramic substrate.

The connection member 110 is formed on a top surface of the substrate 100. The connection member 110 is generally shaped of a sphere or a hemisphere, but embodiments of the present general inventive concept are not limited thereto. The connection member 110 may have an adjustable diameter size to allow the semiconductor package 200 to be stacked at an appropriate interval. The connection member 110 may include, for example, solder balls or conductive bumps, but embodiments of the present general inventive concept are not limited thereto.

At least one of the first metal pad 120 may be formed on the substrate 100. The first metal pad 120 may be connected to a ground GND. As will be described later, the first metal pad 120 may be electrically connected to the shielding material 400.

The semiconductor package 200 is mounted on the connection member 110. The semiconductor package may include a substrate 210, a semiconductor chip (not illustrated), and an encapsulation member (not illustrated). The semiconductor chip may be mounted on the top surface of the substrate 210. Here, the semiconductor chip may be mounted on the top surface of the substrate 210 using a predetermined adhesive material (e.g., a liquid epoxy, an adhesive tape or a conductive medium). Bumps (not illustrated) may be formed on a bottom surface of the semiconductor chip. The bumps of the semiconductor chip may be formed to correspond to, for example, a connection pad (not illustrated) of the substrate 210. That is to say, the semiconductor chip having bumps formed therein is mounted on the top surface of the substrate 210 and may be electrically connected to the substrate 210 through the bumps. The bumps may be formed of, for example, gold (Au), silver (Ag), nickel (Ni), copper (Cu), tin (Sn), or alloys thereof. For example, the bumps may be formed of copper-nickel-lead (Cu—Ni—Pb), copper-nickel-gold (Cu—Ni—Au), copper-nickel (Cu—Ni), nickel-gold (Ni—Au), or nickel-silver (Ni—Ag). The encapsulation member of the semiconductor package 200 may be formed to fill a space between the semiconductor chip and the substrate 210 to protect the bumps and to increase adhesion between the semiconductor chip and the substrate 210. In addition, the encapsulation member of the semiconductor package 200 can maintain the external shape of the semiconductor package 200 and can protect the semiconductor chip from external physical shocks or moisture.

The encapsulation member 300 may be formed to fill a space between a top portion of the substrate 100 and a bottom portion of the semiconductor package 200. The encapsulation member 300 may be formed to fill a space between the substrate 100 and the semiconductor package 200 to protect the connection member 110 and to increase adhesion between the semiconductor package 200 and the substrate 210. In addition, in a case where the shielding material 400 covers the external surface of the encapsulation member 300, the encapsulation member 300 may serve to support the shielding material 400. That is to say, the structure of the shielding material 400 is maintained, so that the shielding material 400 and the first metal pad 120 may be maintained at an electrically connected state. The encapsulation member 300 may be formed of, for example, epoxy molding compound (EMC), silicon resin, polyimide or equivalents thereof, using a molding process.

The shielding material 400 is formed to cover the semiconductor package 200 and the encapsulation member 300. The shielding material 400 is sprayed or injected to external surfaces of the semiconductor package 200 and the encapsulation member 300, covering the semiconductor package 200 and the encapsulation member 300. The shielding material 400 may include, for example, a metallic material.

FIG. 2 is a cross-sectional view illustrating a semiconductor device 2 according to another exemplary embodiment of the present general inventive concept. For the sake of convenient explanation, the following description will focus on differences between the semiconductor device 2 according to the exemplary embodiment illustrated in FIG. 2 and the semiconductor device according to the previous exemplary embodiment.

Referring to FIG. 2, in the semiconductor device 2 according to the present exemplary embodiment of the present general inventive concept, at least one second metal pad 130 may be formed on the semiconductor package 200. For example, the second metal pad 130 may be formed on the substrate 210 of the semiconductor package 200. The second metal pad 130 may be connected to a ground. The second metal pad 130 may be electrically connected to the shielding material 400.

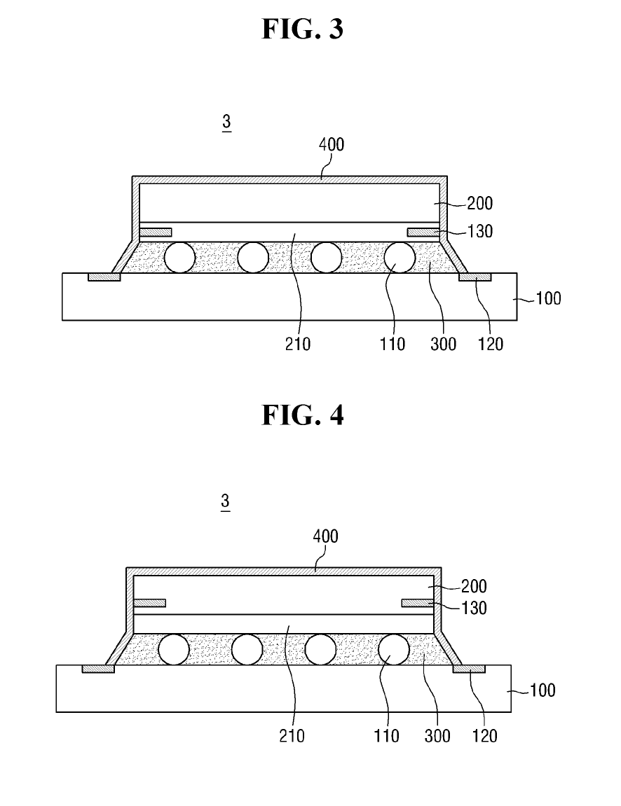

FIGS. 3 and 4 are cross-sectional views illustrating a semiconductor device 3 according to still another exemplary embodiment of the present general inventive concept. For the sake of convenient explanation, the following description will focus on differences between the semiconductor device 3 according to the exemplary embodiment illustrated in FIGS. 3 and 4 and the semiconductor device according to the previous exemplary embodiments.

Referring to FIGS. 3 and 4, in the semiconductor device 3 according to the present exemplary embodiment of the present general inventive concept, at least one first metal pad 120 may be formed on the substrate 100. A second metal pad 130 may be formed on the substrate 210 of the semiconductor package 200 or on a portion of the semiconductor package 200. That is to say, the first and second metal pads 120 and 130 may be simultaneously formed on the substrate 100 and the semiconductor package 200. The first and second metal pads 120 and 130 may be connected to a ground. The first and second metal pads 120 and 130 may be electrically connected to a shielding material 400.

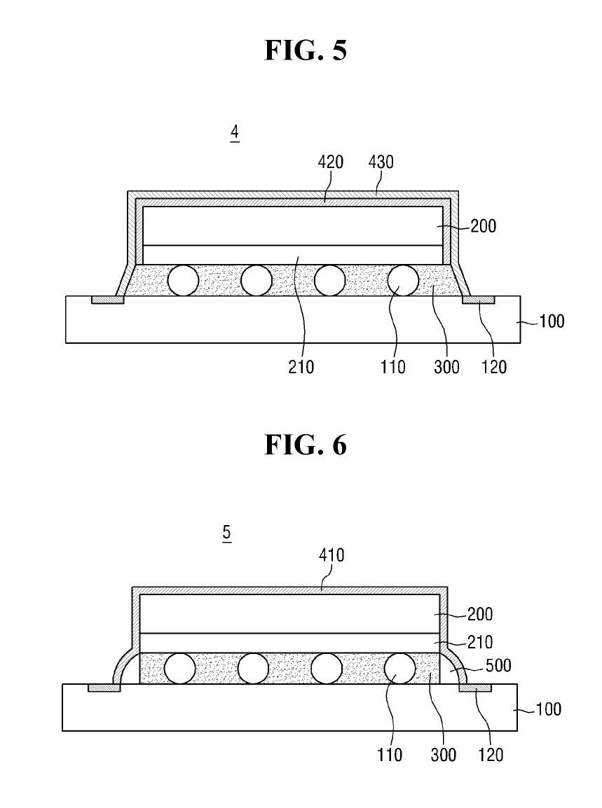

FIG. 5 is a cross-sectional view illustrating a semiconductor device 4 according to still another exemplary embodiment of the present general inventive concept. For the sake of convenient explanation, the following description will focus on differences between the semiconductor device 4 according to the exemplary embodiment illustrated in FIG. 5 and the semiconductor device according to the previous exemplary embodiments.

Referring to FIG. 5, in the semiconductor device 4 according to the present exemplary embodiment of the present general inventive concept, a semiconductor package 200 may be coated with a metallic material 420. That is to say, after the semiconductor package 200 coated with the metallic material 420 is mounted, a shielding material 430 covering the semiconductor package 200 and an encapsulation member 300 may be formed. With this structure, the EMI shielding effect can be increased.

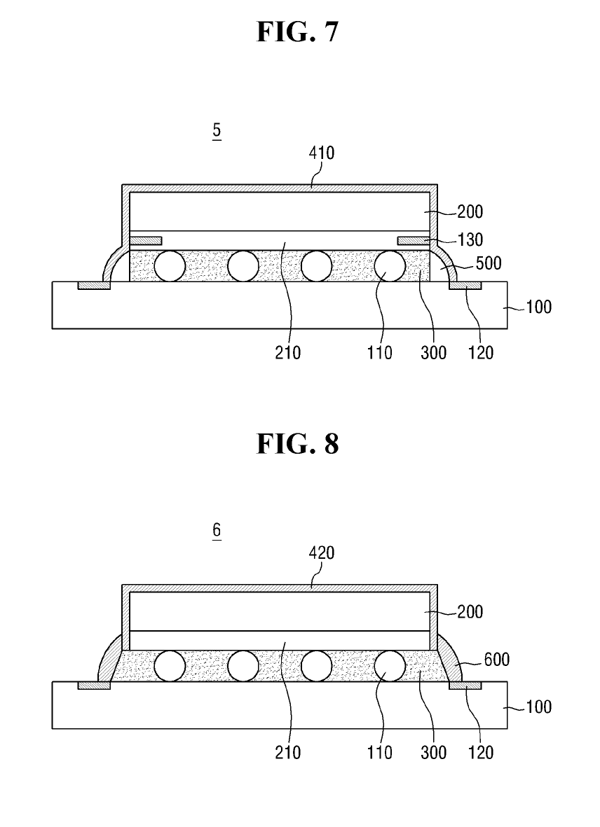

FIGS. 6 and 7 are cross-sectional views illustrating a semiconductor device 5 according to still another exemplary embodiment of the present general inventive concept. For the sake of convenient explanation, the following description will focus on differences between the semiconductor device 5 according to the exemplary embodiment illustrated in FIGS. 6 and 7 and the semiconductor device according to the previous exemplary embodiments.

Referring to FIGS. 6 and 7, the semiconductor device 5 according to the present exemplary embodiment of the present general inventive concept may further include a dam 500 formed on a top surface of a substrate 100 to prevent the encapsulation member 300 from covering the first metal pad 120. The dam 500 may be formed of an insulating material or a conductive material. In particular, the dam 500 may be formed of a highly viscous material. If the encapsulation member 300 overflows to cover the first metal pad 120 in the course of injecting the encapsulation member 300, the shielding material 410 may not be connected to the first metal pad 120, so that it may not be connected to the ground. That is to say, the reliability of the semiconductor device 5 can be improved by forming the dam 500.

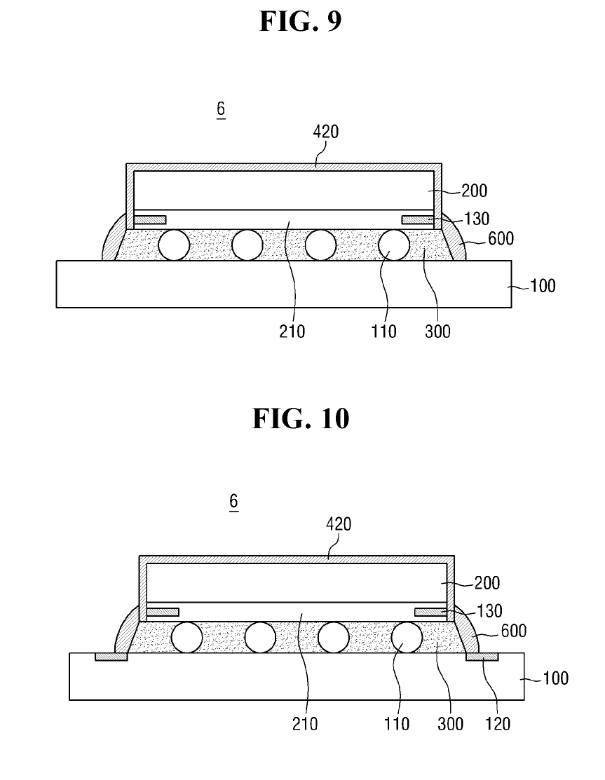

FIGS. 8 to 10 are cross-sectional views illustrating a semiconductor device 6 according to still another exemplary embodiment of the present general inventive concept. For the sake of convenient explanation, the following description will focus on differences between the semiconductor device 6 according to the exemplary embodiment illustrated in FIGS. 8 to 10 and the semiconductor device according to the previous exemplary embodiments.

Referring to FIGS. 8 to 10, in the semiconductor device 6 according to the present exemplary embodiment of the present general inventive concept, after the semiconductor package 200 coated with the metallic material 420 is mounted, an epoxy material 600 contacting a metallic material 420 and a first metal pad 120 may be formed. In particular, the epoxy material 600 may be formed to cover the external surface of the encapsulation member 300. The epoxy material 600 may include an insulating material or a conductive material. The epoxy material 600 may include, for example, high-purity silver, nickel, or conductive graphite, but embodiments of the present general inventive concept are not limited thereto. The epoxy material 600 may be used in adhering a semiconductor, shielding EMI, fixing an electric wire, attaching an electrically heating coil, or assembling an electronic product. The epoxy material 600 may be formed using a room temperature or high temperature curing process.

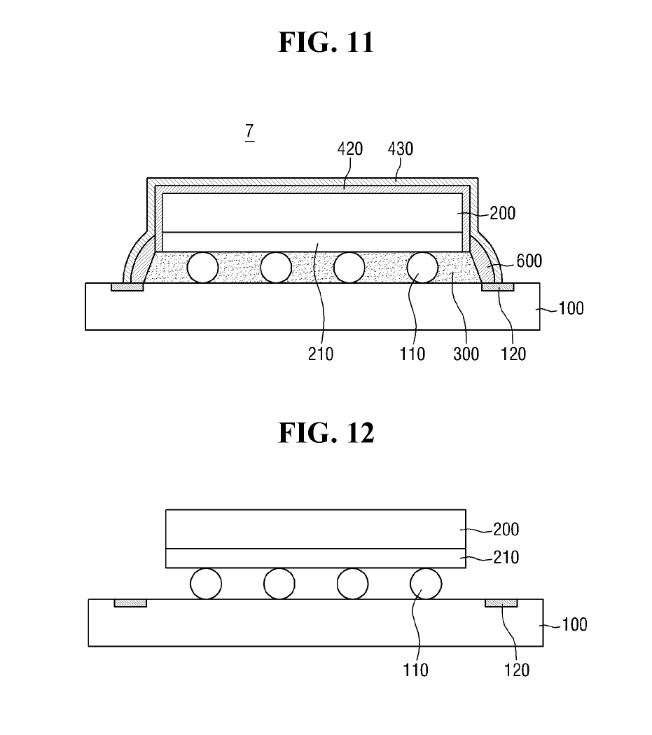

FIG. 11 is a cross-sectional view illustrating a semiconductor device 7 according to still another exemplary embodiment of the present general inventive concept. For the sake of convenient explanation, the following description will focus on differences between the semiconductor device 7 according to the exemplary embodiment illustrated in FIG>11 and the semiconductor device according to the previous exemplary embodiments.

Referring to FIG. 11, in the semiconductor device 7 according to the present exemplary embodiment of the present general inventive concept, a shielding material 430 may be formed to cover a semiconductor package 200 and an epoxy material 600. In a case where the epoxy material 600 is an insulating material, the semiconductor package 200 may be electrically connected to the first metal pad 120 using the shielding material 430. With this structure, the EMI shielding effect can be increased.

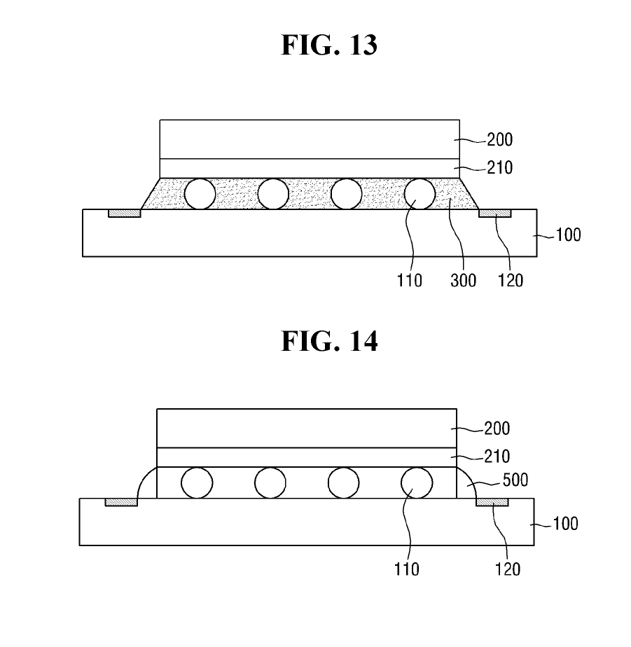

Hereinafter, a method of fabricating a semiconductor device 1 according to an exemplary embodiment of the present general inventive concept will be described with reference to FIGS. 12 and 13 together with FIG. 1. FIGS. 12 and 13 illustrate a method of fabricating a semiconductor device 1 according to an exemplary embodiment of the present general inventive concept.

First, referring to FIG. 12, a connection member 110 is formed on a top surface of a substrate 100, and at least one first metal pad 120 is formed on the substrate 100. Then, a semiconductor package 200 is mounted on the connection member 110.

Referring to FIG. 13, an encapsulation member 300 is injected into a space between a top portion of the substrate 100 and a bottom portion of the semiconductor package 200. The encapsulation member 300 may be an insulating material.

Referring to FIG. 1, the shielding material 400 covering the semiconductor package 200 and the encapsulation member 300 is formed. The shielding material 400 may be formed using a coating process by spraying or an injecting process by molding.

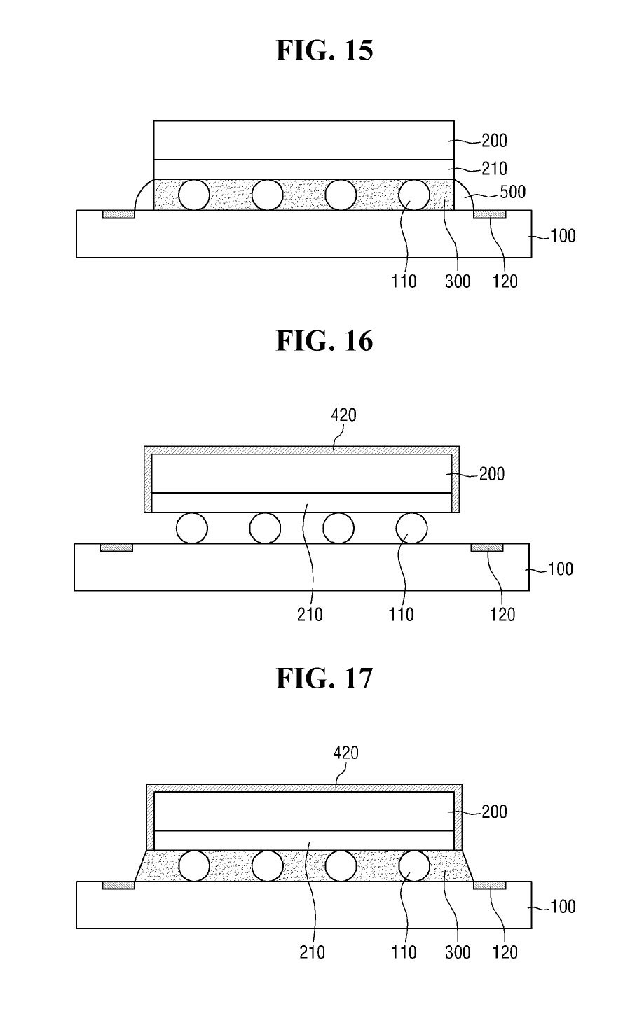

A method of fabricating a semiconductor device 5 according to another exemplary embodiment of the present general inventive concept will be described with reference to FIGS. 14 and 15 together with FIG. 6. For the sake of convenient explanation, the following description will focus on differences between the fabricating method of the semiconductor device 5 according to the exemplary embodiment illustrated in FIGS. 6, 14, and 15 and the fabricating method of the semiconductor device according to the previous exemplary embodiments.

Referring to FIGS. 14 and 15 together with FIG. 6, in the method of fabricating the semiconductor device 5 according to the present exemplary embodiment of the present general inventive concept, after a semiconductor package 200 is mounted, a dam 500 is formed, as illustrated in FIG. 14. An encapsulation member 300 is injected as illustrated in FIG. 15, and a shielding material 410 is formed as illustrated in FIG. 6. The dam 500 may be formed of an insulating material or a conductive material. In addition, the dam 500 may be formed of a highly viscous material. If the encapsulation member 300 overflows to cover the first metal pad 120 in the course of injecting the encapsulation member 300, the shielding material 410 may not be connected to the first metal pad 120, so that it may not be connected to the ground. That is to say, the reliability of the semiconductor device 5 can be improved by forming the dam 500.

A method of fabricating a semiconductor device 6 according to still another exemplary embodiment of the present general inventive concept will be described with reference to FIGS. 16 and 17 together with FIG. 8. For the sake of convenient explanation, the following description will focus on differences between the fabricating method of the semiconductor device 6 according to the exemplary embodiment illustrated in FIGS. 8, 16, and 17 and the fabricating method of the semiconductor device according to the previous exemplary embodiments.

Referring to FIGS. 16 and 17 together with FIG. 8, in the method of the semiconductor device 6 according to still another exemplary embodiment of the present general inventive concept, semiconductor package 200 coated with a metallic material 420 is mounted on a connection member 110, as illustrated in FIG. 16. An encapsulation member 300 filling a space between a top portion of the substrate 100 and a bottom portion of the semiconductor package 200 is injected, as illustrated in FIG. 17. After injecting the encapsulation member 300, an epoxy material 600 covering the encapsulation member 300 is formed, as illustrated in FIG. 8. The epoxy material 600 may be formed in contact with the metallic material 420 and the first metal pad 120.

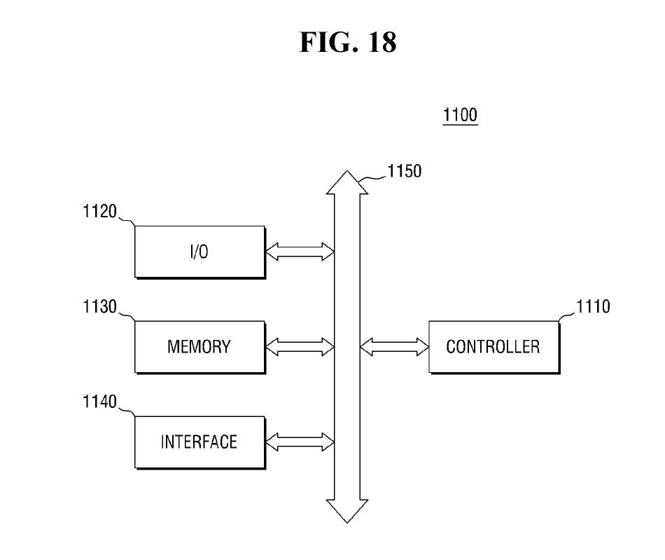

FIG. 18 is a block diagram of an electronic system 1100 incorporating a semiconductor device according to any of the exemplary embodiments of the present general inventive concept.

Referring to FIG. 18, the electronic system 1100 according to the present general inventive concept may include a controller 1110, an input/output (I/O) device 1120, a memory device 1130, an interface 1140 and a bus 1150. The controller 1110, the I/O device 1120, the memory device 1130 and/or the interface 1140 may be connected to each other through the bus 1150. The bus 1150 may correspond to a path through which data moves.

The controller 1110 may include at least one of a microprocessor (not illustrated), a digital signal processor (not illustrated), and a microcontroller (not illustrated), as well as logic devices (not illustrated) capable of performing similar functions to those performed by the microprocessor, digital signal processor, and microcontroller. The I/O device 1120 may include a keypad, a keyboard, a display device, and the like (not illustrated). The memory device 1130 may store data and/or instructions. The interface 1140 may transmit/receive data to/from a communication network. The interface 1140 may be wired or wireless. For example, the interface 1140 may include an antenna (not illustrated) or a wired/wireless transceiver (not illustrated). Although not illustrated, the electronic system 1100 may be used as an operating memory to improve the operation of the controller 1110 and may further include a high-speed DRAM and/or SRAM. A fin-type transistor according to exemplary embodiments of the present general inventive concept may be provided within the memory device 1130 or may be provided as a component of the controller 1110 or the I/O device 1120.

The electronic system 1100 may be applied to a personal digital assistant (PDA) a portable computer, a web tablet, a wireless phone, mobile phone, a digital music player, a memory card, and all similar electronic products capable of transmitting and/or receiving information in a wireless environment.

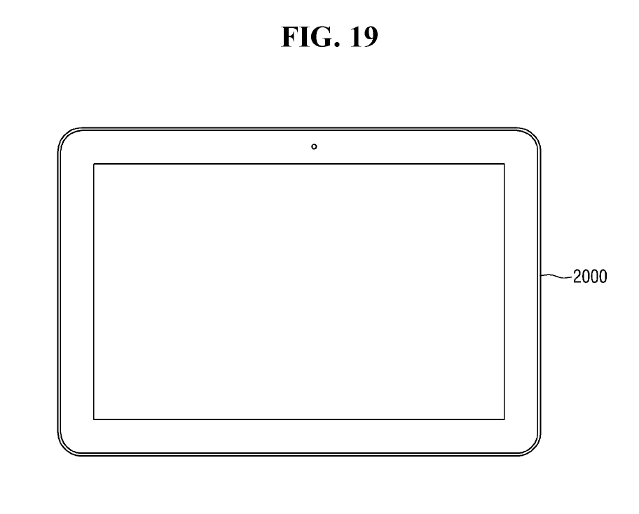

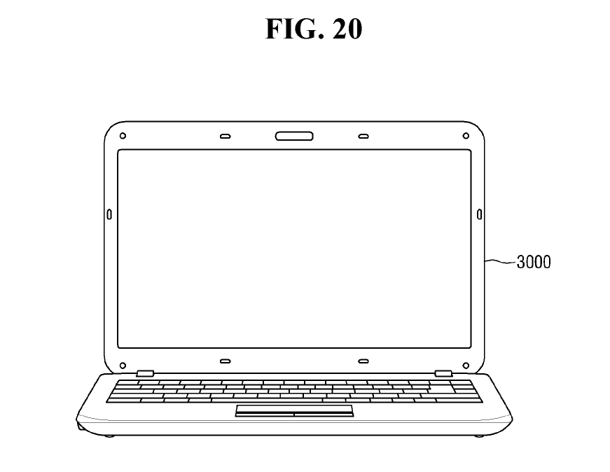

FIGS. 19 and 20 illustrate exemplary semiconductor systems to which a semiconductor device according to any of the exemplary embodiments of the present general inventive concept can be applied. Specifically, FIG. 19 illustrates a tablet PC 2000, and FIG. 20 illustrates a notebook computer 3000. At least one of the semiconductor devices 1 to 7 according to the exemplary embodiments of the present general inventive concept may be used in a tablet PC, a notebook computer, or the like. It will be obvious to one skilled in the art that the semiconductor device according to the exemplary embodiments of the present general inventive concept can be applied to other integrated circuit devices not illustrated herein.

In the present general inventive concept, a shielding material is extended over the semiconductor package and also over the connection member connecting the semiconductor package to the substrate. This structure gives the semiconductor device improved shielding against EMI interference, without increasing the mounting space of the semiconductor device.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor device comprising:
a substrate;
a connection member formed on a top surface of the substrate;
a semiconductor package mounted on the connection member;
an encapsulation member formed to fill a space between a top portion of the substrate and a bottom portion of the semiconductor package; and
a shielding material formed to cover the semiconductor package and the encapsulation member.

2. The semiconductor device of claim 1, wherein the semiconductor package is coated with a metallic material.

3. The semiconductor device of claim 1, wherein:
the substrate includes at least one metal pad; and
the metal pad is electrically connected to a ground and the shielding material.

4. The semiconductor device of claim 1, wherein:
the semiconductor package includes at least one metal pad; and
the metal pad is electrically connected to a ground and the shielding material.

5. A semiconductor device comprising:
a substrate;
a connection member formed on a top surface of the substrate;
a semiconductor package mounted on the connection member and coated with a metallic material;
an encapsulation member formed to fill a space between a top portion of the substrate and a bottom portion of the semiconductor package; and
an epoxy material covering the encapsulation member and formed in contact with the metallic material.

6. The semiconductor device of claim 5, further comprising a shielding material formed to cover the semiconductor package and the epoxy material.

7. The semiconductor device of claim 5, wherein:
the substrate comprises:
at least one metal pad; and
the metal pad is electrically connected to a ground and is formed in contact with the epoxy material.

8. The semiconductor device of claim 5, wherein:
the semiconductor package comprises:
at least one metal pad; and
the metal pad is electrically connected to a ground and the metallic material.

9. A method of fabricating a semiconductor device, the method comprising:
forming a connection member on a top surface of a substrate;
mounting a semiconductor package on the connection member;
injecting an encapsulation member to fill a space between a top portion of the substrate and a bottom portion of the semiconductor package; and
forming a shielding material to cover the semiconductor package and the encapsulation member.

10. The method of claim 9, further comprising:
forming at least one metal pad on the substrate,
wherein the metal pad is electrically connected to a ground and the shielding material.

11. The method of claim 10, further comprising:
forming a dam on the top surface of the substrate to prevent the encapsulation member from covering the metal pad between the mounting of the semiconductor package and the injecting of the encapsulation member.

12. The method of claim 9, further comprising:
forming at least one metal pad on the semiconductor package,
wherein the metal pad is electrically connected to a ground and the shielding material.

13. The method of claim 9, further comprising:
forming at least one first metal pad on the substrate, the at least one first metal pad being electrically connected to a ground and the shielding material; and
forming at least one second metal pad on the semiconductor package, the at least one second metal pad being electrically connected to the ground and the shielding material.

14. A method of fabricating a semiconductor device, the method comprising:
forming a connection member on a top surface of the substrate;
mounting a semiconductor package coated with a metallic material on the connection member;
injecting an encapsulation member to fill a space between a top portion of the substrate and a bottom portion of the semiconductor package; and
forming an epoxy material to cover the encapsulation member, the epoxy material being formed in contact with the metallic material.

15. The method of claim 14, further comprising:
forming a shielding material covering the semiconductor package and the epoxy material.

16. A semiconductor device comprising:
a first substrate;
a connection member formed on a top surface of the first substrate;
a semiconductor package mounted on the connection member;
an encapsulation member formed to fill a space between a top portion of the first substrate and a bottom portion of the semiconductor package; and
a covering material formed to cover the encapsulation member and at least a portion of the semiconductor package.

17. The semiconductor device of claim 16, wherein the covering material is a shielding material to shield against electromagnetic waves.

18. The semiconductor device of claim 17, further comprising:
a metal pad formed on the first substrate, the metal pad being electrically connected to a ground and the shielding material; and
a dam formed on the top surface of the first substrate between the encapsulation member and the metal pad.

19. The semiconductor device of claim 17, wherein:
the semiconductor package comprises:
a second substrate; and
at least one metal pad formed on the second substrate, the metal pad being electrically connected to a ground and to the shielding material.

20. The semiconductor device of claim 17, wherein:
the semiconductor package comprises:
a second substrate; and
at least one metal pad formed on a portion of the semiconductor package other than the second substrate, the metal pad being electrically connected to a ground and to the shielding material.

21. The semiconductor device of claim 16, wherein the portion of the semiconductor package covered by the covering material is coated with a metallic material.

22. The semiconductor device of claim 21, wherein the covering material contacts the metallic material.

23. The semiconductor device of claim 22, wherein the covering material is a shielding material to shield against electromagnetic waves.

24. The semiconductor device of claim 16, wherein the covering material is an epoxy.

25. The semiconductor device of claim 16, wherein the covering material is disposed to cover the semiconductor package.
